(19) United States
(12) Patent Application Publication
(10) Pub. No.: US 2007/0034991 A1
(43) Pub. Date: Feb. 15, 2007

(54) Semiconductor device

(75) Inventor: Masaharu Sato, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/499,642

(22) Filed: Aug. 7, 2006

(30) Foreign Application Priority Data
Aug. 11, 2005 (JP) 2005-233140

(51) Int. Cl. H01L 29/00

(52) U.S. Cl. 257/547

(57) ABSTRACT

To reduce the ratio of the area of a diode region relative to the chip area. A semiconductor device comprises an insulated gate transistor formed on a substrate 1, a plurality of diodes D1, D2, and D3 formed on the substrate 1 and connected in serial between the gate of the insulated gate transistor and a terminal, and a diode array that breaks down when a surge voltage from the terminal is applied. The diode array is formed on the P-type substrate 1 and the diodes D1, D2, and D3 respectively has a plurality of N-type wells 2a, 2b, and 2c, which serve as cathodes. The sizes of spaces S1 between the N-type wells 2a and 2b, and S2 between the N-type wells 2b and 2c are different.

### FIELD OF THE INVENTION

The present invention relates to a semiconductor device in which a transistor and a clamp diode are formed on the same semiconductor substrate and particularly to a semiconductor device in which the ratio of the area of a diode region to the chip area can be reduced.

### BACKGROUND OF THE INVENTION

Among conventional semiconductor devices, there are ones in which a transistor and a clamp diode are formed on the same semiconductor substrate (chip). For instance, as a semiconductor device having an insulated gate transistor, there is one in which a Zener diode group for boosting the gate voltage is formed in the chip with one end being connected to the gate terminal of an LDMOSFET, which is also formed in the chip, a pad for connecting the booster elements is formed on the chip being electrically connected to the other end of the Zener diode group, and a bonding wire connected to the high voltage terminal of the LDMOSFET in parallel to the Zener diode group outside the IC chip is a parasitic inductance when a surge is applied (refer to Patent Document 1). In the semiconductor device described in Patent Document 1, if a surge voltage is applied to the drain side (power supply side) of the LDMOSFET while the source is in its GND state, the LDMOSFET will be protected from the surge because a surge current flows through the Zener diode group and the potential of the gate terminal increases when a positive surge voltage exceeds the clamp voltage, and the LDMOSFET operates and the current flows in the drain.

Further, as a semiconductor device having a bipolar transistor, there is one in which three anode regions and three cathode regions for a plurality (three) of diodes are provided while a collector region, a base region, and an emitter region are formed on a semiconductor substrate, the three diodes are connected in series, and this serial circuit is connected between the base and collector of the transistor (refer to Patent Document 2). In the composite semiconductor element described in Patent Document 2, the transistor is protected from a surge because a surge current flows in the base through the diodes when a surge voltage applied to the collector exceeds the clamp voltage and the transistor starts to operate.

Further, in order to increase the clamp voltage, a technique in which a plurality of diodes are connected in series as described in Patent Documents 1 and 2 is generally used. The distances between these diodes are all equal as described in Patent Document 2.

For instance, referring to FIG. 12, in a diode array of a semiconductor device having an insulated gate transistor, N-type wells 102a, 102b, and 102c, which serve as cathodes, are formed on a P-type silicon substrate 101, N+ diffusion regions 103a, 103b, and 103c, which serve as cathode electrodes, are respectively formed in the N-type wells 102a, 102b, and 102c, P+ diffusion regions 104a, 104b, and 104c, which serve as anodes, are respectively formed in the N-type wells 102a, 102b, and 102c, an insulating film 105 made up of a silicon oxide film is formed on the P-type silicon substrate 101, the N+ diffusion region 103a is electrically connected to the drain of the transistor (not shown in the drawing) via a wiring layer 106a, the P+ diffusion region 104a and the N+ diffusion region 103b are electrically connected via a wiring layer 106b, the P+ diffusion region 104b and the N+ diffusion region 103c are electrically connected via a wiring layer 106c, and the P+ diffusion region 104c is electrically connected to the gate of the transistor (not shown in the drawing) via a wiring layer 106d. Spaces (distances) S1 and S2 between the N-type wells 102a, 102b, and 102c, adjacent to each other, are equal.

[Patent Document 1]

Japanese Patent Kokai Publication No. JP-P2000-269435A

[Patent Document 2]

Japanese Patent Kokai Publication No. JP-A-8-227941

### SUMMARY OF THE DISCLOSURE

However, when the spaces between the neighboring N-type wells 102a, 102b, and 102c are equal as in the conventional semiconductor device, the ratio of the area of the diode region (the region where the diode array is disposed) to the chip area increases. Particularly, since depletion layers extending from the N-type wells 102a, 102b, and 102c in the direction where the impurity concentration is low expands more when the necessary clamp voltage is increased (refer to FIG. 13), spaces S1′ and S2′ between the neighboring N-type wells 102a, 102b, and 102c must be large as shown in FIG. 14 in order to prevent the short circuit that occurs when depletion layers connect with each other. Further, even when P-type insulating regions 107 are provided between the neighboring N-type wells 102a, 102b, and 102c as shown in FIGS. 15 and 16, spaces S1″, S2″, and S3″ between the N-type wells 102a, 102b and 102c, and the P-type insulating regions 107 must still be large. Therefore, the higher the clamp voltage is, the more notable the increase in the area of the diode region becomes. Further, since a plurality of such diode regions are provided on a chip, the area of diode regions increases cumulatively in the conventional structure.

It is a problem to be solved in the present invention to reduce the ratio of the area of a diode region to the chip area. The other problems to be solved in the present invention will become apparent from the entire disclosure.

According to a first aspect of the present invention, a semiconductor device comprises: a transistor formed on a substrate and having a first electrode connected to a terminal, a second electrode connected to a power supply line or a ground, and a third electrode; and a diode array including a plurality of diodes formed on the substrate and connected in series between the third electrode and the terminal and/or between the third electrode and the power supply line or the ground, provided that the diode array breaks down when a surge voltage from the terminal is applied. The diode array comprises a plurality of second conductivity type regions for each of the diodes, which regions are formed on a first conductivity type substrate, and are of the opposite conductivity type to the first conductivity type, serving as anode regions or cathode regions. The sizes of spaces between the neighboring second conductivity type regions are all different or the size of at least one of spaces is different from those of other spaces while some spaces are the same size.

According to a second aspect of the present invention, a semiconductor device comprises: a transistor formed on a substrate and having a first electrode connected to a power supply line, a second electrode connected to a terminal or a ground, and a third electrode; and a diode array including a plurality of diodes formed on the substrate. The diodes are connected in series between the third electrode and the power supply line and/or between the third electrode and the terminal or the ground, provided that the diode array breaks down when a surge voltage from the power supply line is applied. The diode array comprises a plurality of second conductivity type regions for each of the diodes, which regions are formed on a first conductivity type substrate, and are of the opposite conductivity type to the first conductivity type, serving as anode regions or cathode regions. The sizes of spaces between the neighboring second conductivity type regions are all different, or the size of at least one of spaces is different from other spaces while some spaces are the same size.

In a third aspect of the present invention, among spaces between the neighboring second conductivity type regions, the larger is a voltage difference from a substrate voltage, the wider is the space neighboring the second conductivity type region.

In a fourth aspect of the present invention, it is preferable that first conductivity type insulating regions be formed between the neighboring second conductivity type regions on the first conductivity type substrate.

In a fifth aspect of the present invention, it is preferable that on both sides of the insulating regions, the sizes of spaces between the insulating regions and the second conductivity type regions be all different, or that the size of at least one space be different from those of other spaces while some spaces are the same size.

In a sixth aspect of the present invention, on both sides of the insulating regions, among the spaces between the insulating regions and the second conductivity type regions, the larger is a voltage difference from a substrate voltage, the wider is the space neighboring the second conductivity type region.

In a seventh aspect, the transistor comprises an insulated gate transistor and the third electrode is a gate.

In an eighth aspect, the transistor comprises a bipolar transistor and the third electrode is a base when the second electrode is connected to the ground.

The meritorious effects of the present invention are summarized as follows.

According to the present invention (aspects 1 to 8), it becomes possible to reduce the ratio of the occupation area of the diode region to the chip area by varying the size of the spaces between the second conductivity type regions in consideration of the depletion layers formed around the second conductivity type regions, thereby reducing the chip area. Further, since a plurality of such diode regions are provided on a chip, the area of the diode regions can be effectively reduced by arranging several diode arrays.

According to the present invention (aspects 3 to 5), compared to the conventional structures, the ratio of the occupation area of the diode regions to the chip area can be reduced even in a structure where the insulating regions are provided between the neighboring second conductivity type regions, thereby reducing the chip area.

According to the present invention (aspects 4 and 5), lengths necessary can be changed by varying, on both sides of the insulating regions, the spaces between the insulating regions and the second conductivity type regions, corresponding to an actual maximum voltage applied.

### BRIEF DESCRIPTION OF THE DRAWINGS

FIG. 1 is a circuit diagram schematically showing the structure of a semiconductor device (an insulated gate type) relating to an Embodiment 1 of the present invention.

FIG. 2 is a circuit diagram schematically showing the structure of a variation of the semiconductor device (an insulated gate type) relating to Embodiment 1 of the present invention.

FIG. 3 is a circuit diagram schematically showing the structure of a semiconductor device (a bipolar type) relating to Embodiment 1 of the present invention.

FIG. 4 is a circuit diagram schematically showing the structure of a first variation of the semiconductor device (a bipolar type) relating to Embodiment 1 of the present invention.

FIG. 5 is a circuit diagram schematically showing the structure of a second variation of the semiconductor device (a bipolar type) relating to Embodiment 1 of the present invention.

FIG. 6 is a circuit diagram schematically showing the structure of a third variation of the semiconductor device (a bipolar type) relating to Embodiment 1 of the present invention.

FIG. 7 is a partial plan view schematically showing the structure of a diode array of the semiconductor device relating to Embodiment 1 of the present invention.

FIG. 8 is a partial cross-sectional view (taken along a line X-X′ in FIG. 7) schematically showing the structure of the diode array of the semiconductor device relating to Embodiment 1 of the present invention.

FIG. 9 is a plan view schematically showing the arrangement of the diode arrays of the semiconductor device relating to Embodiment 1 of the present invention.

FIG. 10 is a partial plan view schematically showing the structure of a diode array of a semiconductor device relating to Embodiment 2 of the present invention.

FIG. 11 is a partial cross-sectional view (taken along a line Y-Y′ in FIG. 10) schematically showing the structure of the diode array of the semiconductor device relating to Embodiment 2 of the present invention.

FIG. 12 is a partial cross-sectional view schematically showing the structure of a diode array of a semiconductor device relating to a first conventional example.

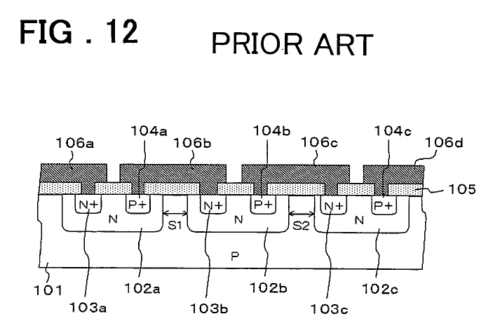

FIG. 13 is a schematic diagram for explaining the expansion of a depletion layer formed in the diode array of the semiconductor device relating to the first conventional example.

FIG. 14 is a partial cross-sectional view schematically showing the structure of a diode array of a semiconductor device relating to a second conventional example.

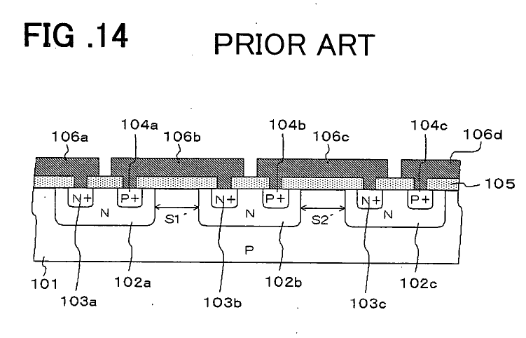

FIG. 15 is a partial plan view schematically showing the structure of a diode array of a semiconductor device relating to a third conventional example.

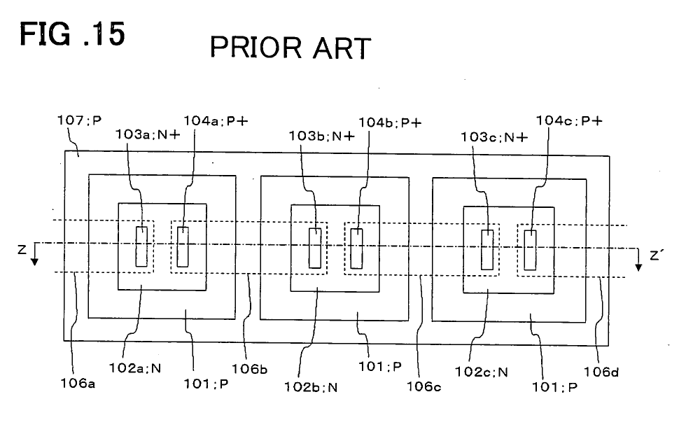

FIG. 16 a partial cross-sectional view (taken along a line Z-Z′ in FIG. 15) schematically showing the structure of the diode array of the semiconductor device relating to the third conventional example.

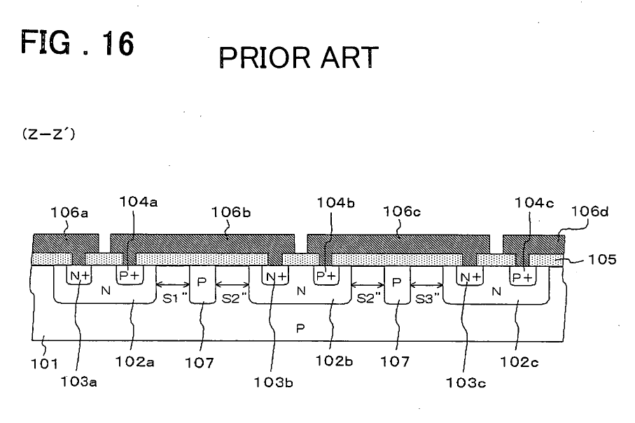

### PREFERRED EMBODIMENTS OF THE INVENTION

### Embodiment 1

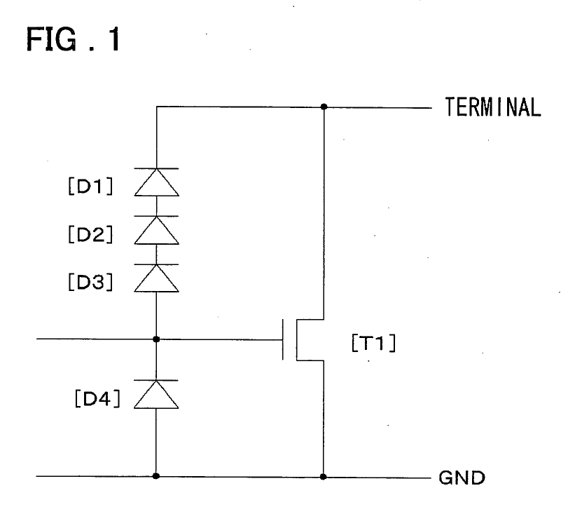

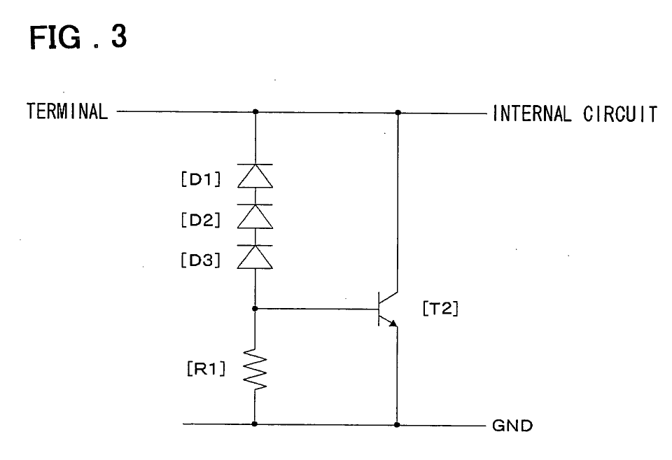

A semiconductor device relating to Embodiment 1 of the present invention will be described. First, a circuit to which the semiconductor device relating to Embodiment 1 of the present invention is applied will be described with reference to the drawings. FIG. 1 is a circuit diagram schematically showing the structure of the (insulated gate) semiconductor device relating to Embodiment 1 of the present invention. FIG. 3 is a circuit diagram schematically showing the structure of the (bipolar) semiconductor device relating to Embodiment 1 of the present invention.

[Insulated Gate Type]

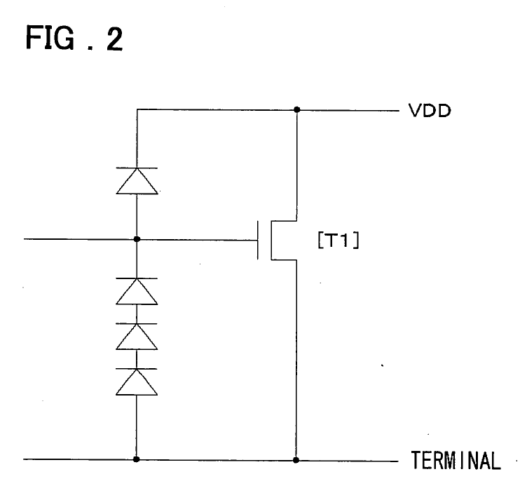

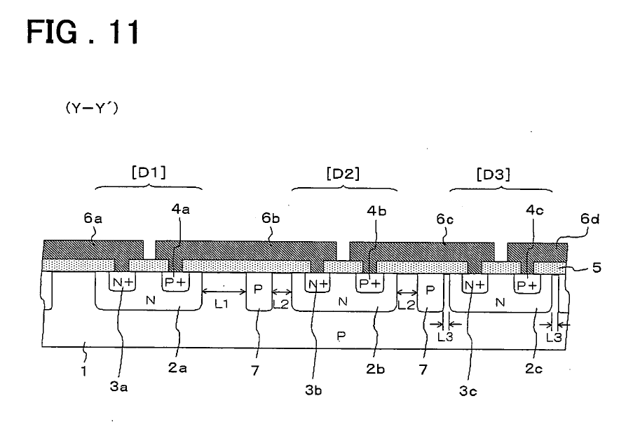

Referring to FIG. 1, this semiconductor device is a terminal-internal circuit-GND type and comprises an insulated gate transistor T1 and diodes D1, D2, D3, and D4. The drain of the insulated gate transistor T1 is electrically connected to a terminal. The source of the insulated gate transistor T1 is electrically connected to the ground GND. The diodes D1, D2, and D3 are connected in serial so that their cathodes point towards the terminal. Note that the number of the diodes is not limited to three. It should be three or more when there is no P-type insulating region (7 in FIG. 11) and it should be two or more when the P-type insulating regions (7 in FIG. 11) are provided. The cathode of the diode D1 is electrically connected to the drain of the insulated gate transistor T1 and to the terminal. The anode of the diode D3 is electrically connected to the gate of the insulated gate transistor T1 and to the cathode of the diode D4. The cathode of the diode D4 is electrically connected to the anode of the diode D3 and to the gate of the insulated gate transistor T1. The anode of the diode D4 is electrically connected to the source of the insulated gate transistor T1 and to the ground. Note that, as a variation of the device shown in FIG. 1, a structure shown in FIG. 2 (a VDD-terminal type in which a P channel is used in an insulated gate transistor) is possible.

In the circuit shown in FIG. 1, when a high voltage is applied to the terminal and it exceeds the withstandable total breakdown voltage of the diodes D1, D2, D3 and D4, a current flows through the diode D4 via the diodes D1, D2, and D3. Because of this, a bias is applied to the gate of the insulated gate transistor T1, the drain and the source of the insulated gate transistor T1 become conductive, and the current flows from the terminal to the ground. As a result, a further increase in the potential of the terminal can be prevented, thereby protecting the insulated gate transistor T1 from being damaged.

[Bipolar Type]

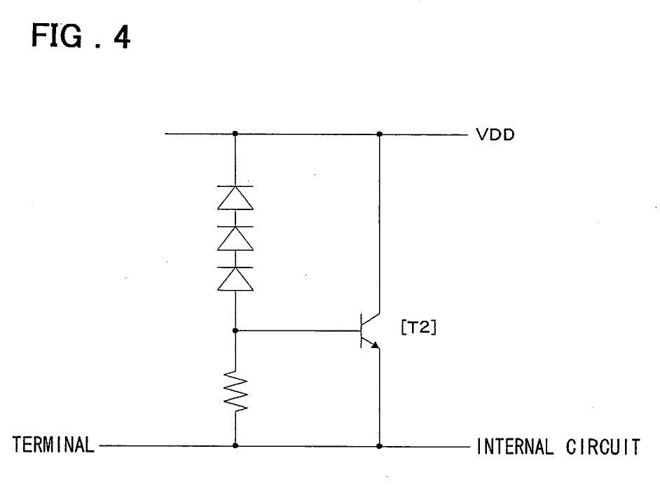

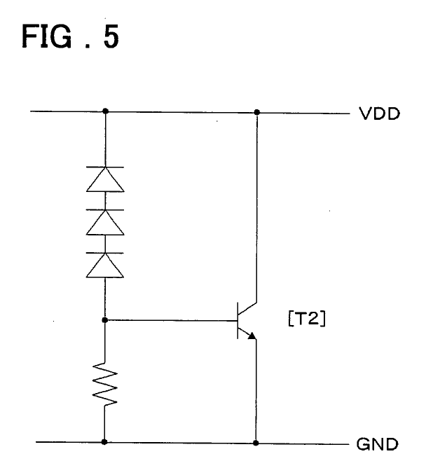

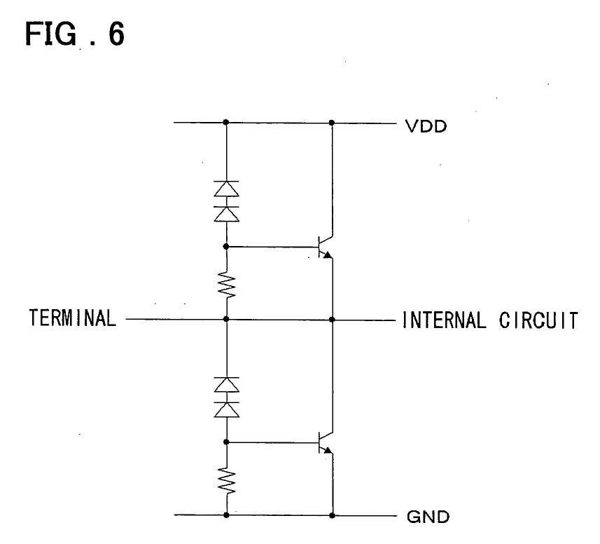

Referring to FIG. 3, this semiconductor device is a terminal-internal circuit-GND type and comprises a bipolar transistor T2, diodes D1, D2, and D3, and a resistor R1. The collector of the bipolar transistor T2 is electrically connected to the terminal and the internal circuit. The emitter of the bipolar transistor T2 is electrically connected to the ground. The diodes D1, D2, and D3 are connected in serial so that their cathodes point towards the terminal. Note that the number of the diodes is not limited to three. It should not be less than three when there is no P-type insulating region (7 in FIG. 11) and it should be no less than two when the P-type insulating regions (7 in FIG. 11) are provided. The cathode of the diode D1 is electrically connected to the collector of the bipolar transistor T2, the terminal, and the internal circuit. The anode of the diode D3 is electrically connected to the base of the bipolar transistor T2 and the resistor R1. One end of the resistor R1 is electrically connected to the anode of the diode D3 and the base of the bipolar transistor T2. The other end of the resistor R1 is electrically connected to the emitter of the bipolar transistor T2 and the ground. As variations of the device shown in FIG. 3, structures shown in FIG. 4 (a VDD-terminal-internal circuit type), FIG. 5 (a VDD-GND type), and FIG. 6 (a composite of the VDD-terminal-internal circuit type and the terminal-internal circuit-GND type) are possible.

In the circuit shown in FIG. 3, when a high voltage is applied to the terminal or to the internal circuit and it exceeds the total breakdown voltage of the diodes D1, D2, and D3, a current flows through the base of the bipolar transistor T2 and the resistor R1 via the diodes D1, D2, and D3. Because of the fact that the current flows through the base of the bipolar transistor T2, the collector and emitter of the bipolar transistor T2 become conductive and the current flows from the terminal or the internal circuit to the ground. As a result, a further increase in the potential of the terminal or the internal circuit can be prevented, thereby protecting the internal circuit and the bipolar transistor T2 from being damaged.

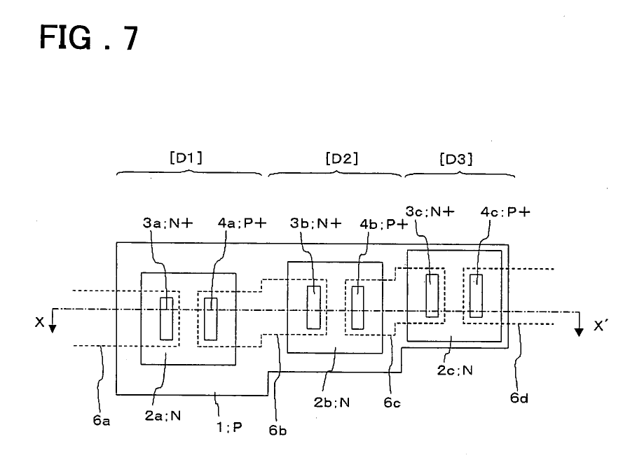

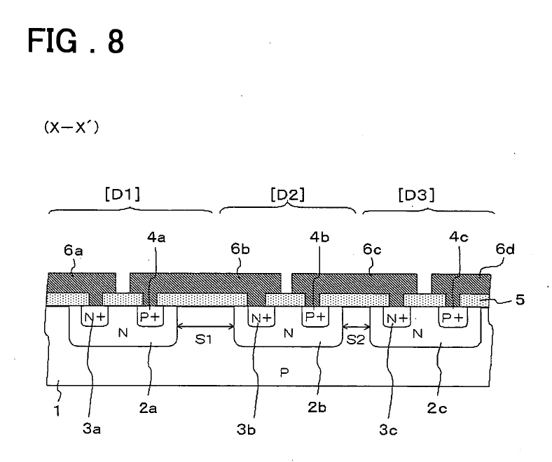

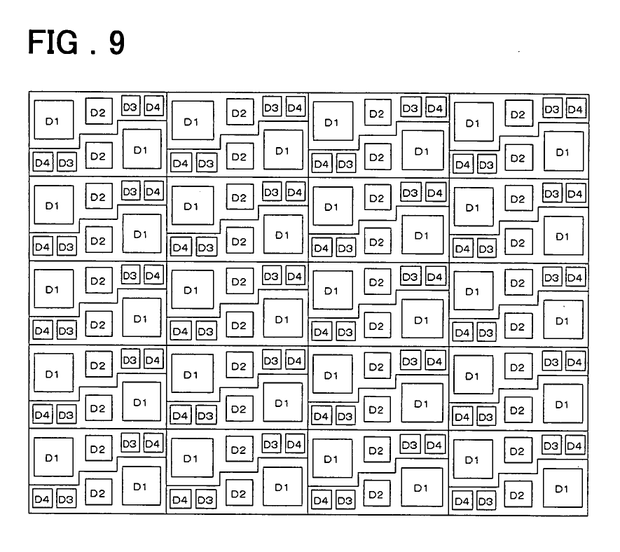

Next, a diode array of the semiconductor device relating to Embodiment 1 of the present invention will be described with reference to the drawings. FIG. 7 is a partial plan view schematically showing the structure of the diode array of the semiconductor device relating to Embodiment 1 of the present invention. FIG. 8 is a partial cross-sectional view (taken along a line X-X′ in FIG. 7) schematically showing the structure of the diode array of the semiconductor device relating to Embodiment 1 of the present invention. FIG. 9 is a plan view schematically showing the arrangement of the diode arrays of the semiconductor device relating to Embodiment 1 of the present invention. Note that the diode array shown in FIGS. 7 and 8 is created by combining the diodes D1, D2, and D3 in FIGS. 1 and 3. Parts other than the diode array (such as the transistor) is structured similarly to the conventional examples.

Referring to FIGS. 7 and 8, in the diode array of this semiconductor device, N-type wells 2a, 2b, and 2c, which serve as cathodes, are formed on a P-type silicon substrate 1, N+ diffusion regions 3a, 3b, and 3c, which serve as cathode electrodes, are respectively formed in the N-type wells 2a, 2b, and 2c, P+ diffusion regions 4a, 4b, and 4c, which serve as anodes, are respectively formed in the N-type wells 2a, 2b, and 2c, an insulating film 5 made up of a silicon oxide film is formed on the P-type silicon substrate 1, the N+ diffusion region 3a is electrically connected to a transistor (not shown in the drawing; it is connected to the drain in the case of the insulated gate type in FIG. 1 and to the collector in the case of the bipolar type) via a wiring layer 6a, the P+ diffusion region 4a and the N+ diffusion region 3b are electrically connected via a wiring layer 6b, the P+ diffusion region 4b and the N+ diffusion region 3c are electrically connected via a wiring layer 6c, and the P+ diffusion region 4c is electrically connected to the transistor (not shown in the drawing; it is connected to the gate in the case of the insulated gate type in FIG. 1 and to the base in the case of the bipolar type) via a wiring layer 6d. The sizes of spaces S1 and S2 between the neighboring N-type wells 2a, 2b, and 2c are different.

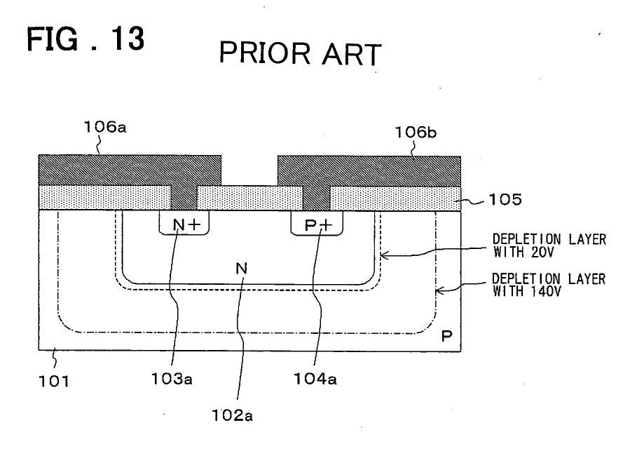

The space S1, adjacent to the diode D1 (the one closest to the terminal in FIG. 1 or 3) to which a high voltage is applied (i.e., the difference from the substrate voltage is large) when a surge voltage occurs, is larger than the space S2, adjacent to the diode D3, to which a low voltage is applied in such a case. This is because a depletion layer formed around the N-type well 2a in the diode D1, to which a high voltage is applied because of the wiring, expands more (refer to FIG. 13), and it will prevent the depletion layer in the diode D1 from being connected to the depletion layer formed around the N-type well 2b in the diode D2. Note that, when four or more diodes are provided in a diode array, the number of spaces between N-type wells is three or more. In this case, the size of each space should be different or the size of at least one space should be different while others may be the same size.

A PN separation-type device is shown in FIGS. 7 and 8, however, the P-type silicon substrate 1, the N-type wells 2a, 2b, and 2c, the N+ diffusion regions 3a, 3b, and 3c, and the P+ diffusion regions 4a, 4b, and 4c may respectively be of the opposite conductivity type. In that case, the direction of the anodes and cathodes is reversed and the connection structure of the transistor corresponds to the direction of the anodes and cathodes.

According to Embodiment 1, as shown in FIG. 7, it becomes possible to reduce the ratio of the occupation area of the diode region to the chip area by taking the depletion layers formed around the cathode regions (the N-type wells 2a, 2b, and 2c) into consideration so as to vary the size of the spaces between the cathode regions, thereby reducing the chip area. Further, since a plurality of such diode regions are provided on a chip, the area of the diode regions can be effectively reduced by arranging diode arrays as shown in FIG. 9.

### Embodiment 2

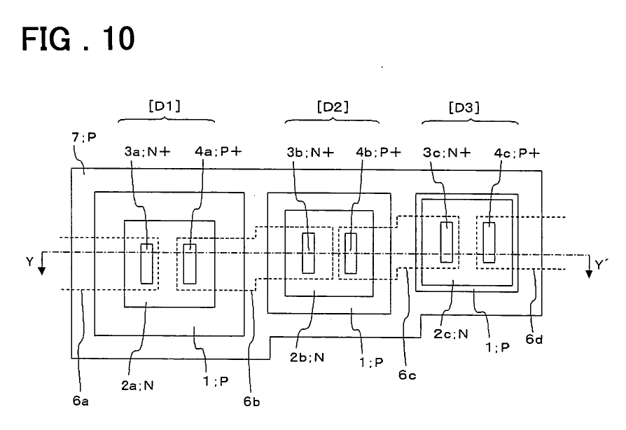

A diode array of a semiconductor device relating to Embodiment 2 of the present invention will be described with reference to the drawings. FIG. 10 is a partial plan view schematically showing the structure of the diode array of the semiconductor device relating to Embodiment 2 of the present invention. FIG. 11 is a partial cross-sectional view (taken along a line Y-Y′ in FIG. 10) schematically showing the structure of the diode array of the semiconductor device relating to Embodiment 2 of the present invention. Note that the diode array shown in FIGS. 10 and 11 is created by combining the diodes D1, D2, and D3 in FIGS. 1 and 3. Parts other than the diode array (such as the transistor) is structured similarly to the conventional examples.

The difference between Embodiment 1 and Embodiment 2 is that P-type insulating regions 7 are provided between the plurality (two or more) of the diodes D1, D2, and D3 (between the neighboring N-type wells 2a, 2b, and 2c) connected in serial in the diode array of the semiconductor device relating to Embodiment 2. The P-type insulating regions 7 are arranged taking the size of the depletion layers that form around the N-type wells 2a, 2b, and 2c of the diodes D1, D2, and D3 when the clamp voltage is high into consideration. In other words, the breakdown voltage of the N-type wells 2a, 2b, and 2c of the diodes D1, D2, and D3 and the P-type insulating regions 7 depends on the distance from each other. The necessary breakdown voltage of the N-type wells 2a, 2b, and 2c of the diodes D1, D2, and D3 and the P-type insulating regions 7 should be equal to or more than the breakdown voltage at the time of clamping, and it is lower on the side of a lower voltage. Therefore, a length L1 between the N-type well 2a and the P-type insulating region 7, a length L2 between the N-type well 2b and the P-type insulating region 7, and a length L3 between the N-type well 2c and the P-type insulating region 7 are all different. In FIGS. 10 and 11, the length L1 between the N-type well 2a, to which a high voltage is applied because of the wiring, and the P-type insulating region 7 is longer than the length L2 between the N-type well 2b and the P-type insulating region 7, and the length L2 between the N-type well 2b and the P-type insulating region 7 is longer than the length L3 between the N-type well 2c on the lower voltage side and the P-type insulating region 7.

According to Embodiment 2, lengths necessary can be varied by varying the lengths between the P-type insulating region 7 and the N-type wells 2a and between the P-type insulating region 7 and the N-type wells 2b (the lengths between the P-type insulating region 7 and the N-type wells 2b and between the P-type insulating region 7 and the N-type wells 2c) corresponding to an actual maximum voltage applied. Further, compared to the conventional structures, the ratio of the occupation area of the diode regions to the chip area can be reduced even in the structure where the P-type insulating regions 7 are provided between the N-type wells 2a, 2b, and 2c, thereby reducing the chip area.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising:
a transistor formed on a substrate and having a first electrode connected to a terminal, a second electrode connected to a power supply line or a ground, and a third electrode; and
a diode array including a plurality of diodes formed on said substrate and connected in series between said third electrode and said terminal and/or between said third electrode and said power supply line or said ground, provided that said diode array breaks down when a surge voltage from said terminal is applied; wherein
said diode array comprises a plurality of second conductivity type regions for each of said diodes, said second conductivity type regions being formed on a first conductivity type substrate, and said second conductivity type regions being of the opposite conductivity type to the first conductivity type, said second conductivity type regions serving as anode regions or cathode regions, the sizes of spaces between said neighboring second conductivity type regions being all different or the size of at least one of spaces between said neighboring second conductivity type regions being different from those of other spaces while some spaces between said neighboring second conductivity type regions are the same size.

2. A semiconductor device comprising:
a transistor formed on a substrate and having a first electrode connected to a power supply line, a second electrode connected to a terminal or a ground, and a third electrode; and
a diode array including a plurality of diodes formed on said substrate, said diodes being connected in series between said third electrode and said power supply line and/or between said third electrode and said terminal or said ground, provided that said diode array breaks down when a surge voltage from said power supply line is applied; wherein
said diode array comprises a plurality of second conductivity type regions for each of said diodes, said second conductivity type regions being formed on a first conductivity type substrate, and said second conductivity type regions being of the opposite conductivity type to the first conductivity type, said second conductivity type regions serving as anode regions or cathode regions, the sizes of spaces between the neighboring second conductivity type regions being all different, or the size of at least one of spaces between said neighboring second conductivity type regions being different from other spaces while some spaces between said neighboring second conductivity type regions are the same size.

3. The semiconductor device as defined in claim 1 wherein among spaces between said neighboring second conductivity type regions, the larger is a voltage difference of said second conductivity type region from a substrate voltage, the wider is the space.

4. The semiconductor device as defined in claim 2 wherein among spaces between said neighboring second conductivity type regions, the larger is a voltage difference of said second conductivity type region from a substrate voltage, the wider is the space.

5. The semiconductor device as defined in claim 1 wherein first conductivity type insulating regions are formed between said neighboring second conductivity type regions on said first conductivity type substrate.

6. The semiconductor device as defined in claim 2 wherein first conductivity type insulating regions are formed between said neighboring second conductivity type regions on said first conductivity type substrate.

7. The semiconductor device as defined in claim 5 wherein on both sides of said insulating regions, the sizes of spaces between said insulating regions and said second conductivity type regions are all different, or the size of at least one space is different from those of other spaces while some spaces are the same size.

8. The semiconductor device as defined in claim 6 wherein on both sides of said insulating regions, the sizes of spaces between said insulating regions and said second conductivity type regions are all different, or the size of at least one space is different from those of other spaces while some spaces are the same size.

9. The semiconductor device as defined in claim 7 wherein on both sides of said insulating regions, among the spaces between said insulating regions and said second conductivity type regions, the larger is a voltage difference of a space neighboring said second conductivity type region from a substrate voltage, the wider is the space.

10. The semiconductor device as defined in claim 8 wherein on both sides of said insulating regions, among the spaces between said insulating regions and said second conductivity type regions, the larger is a voltage difference of a space neighboring said second conductivity type region from a substrate voltage, the wider is the space.

11. The semiconductor device as defined in claim 1 wherein said transistor is an insulated gate transistor and said third electrode is a gate.

12. The semiconductor device as defined in claim 2 wherein said transistor is an insulated gate transistor and said third electrode is a gate.

13. The semiconductor device as defined claim 1 wherein said transistor is a bipolar transistor, and said third electrode is a base when said second electrode is connected to said ground.

14. The semiconductor device as defined claim 2 wherein said transistor is a bipolar transistor, and said third electrode is a base when said second electrode is connected to said ground.
